(19) United States
(12) Patent Application Publication
(10) Pub. No.: US 2008/0280067 A1
(43) Pub. Date: Nov. 13, 2008

(54) Method of forming a carbon film on a metal substrate at a low temperature

(75) Inventors: Shi-Kun Chen, Taichung (TW); Tse-Hao Ko, Taichung (TW); Chih-Yeh Chung, Taichung (TW); Po-Jen Chu, Taichung (TW); Cheng-Hao Huang, Taichung (TW)

Correspondence Address: BACON & THOMAS, PLLC, 625 SLATERS LANE, FOURTH FLOOR, ALEXANDRIA, VA, 22314-1176, US

(73) Assignee: FENG CHIA UNIVERSITY, Taichung (TW)

(21) Appl. No.: 11/798,078

(22) Filed: May 10, 2007

(51) Int. Cl. C23C 16/26; C25D 5/00

(52) U.S. Cl. 427/577; 205/80; 427/249.1; 427/585

(57) ABSTRACT

A method of forming a carbon film on a metal substrate at a low temperature has steps of preparing a metal substrate having a softening temperature; forming a catalytic layer having a thickness of greater than 0.01 μm on the metal substrate, and forming a carbon film on the catalytic layer by chemical vapor deposition (CVD) at a reaction temperature less than the softening temperature of the metal substrate. A carbonaceous material is carried into a CVD reaction area by a carrier gas and is thermally decomposed at a reaction temperature between 300° C. and 1000° C. to form the carbon film having a thickness between 0.1 μm and 10 μm on the catalytic layer.

### BACKGROUND OF THE INVENTION

1. Field of Invention

The present invention relates to a fuel cell, and more particularly to a method for forming a carbon film on a metal substrate at a low temperature that can form a fine carbon film having high conductivity, being anticorrosive and bonding well to the metal substrate.

2. Description of the Related Art

Conventional materials for manufacturing bipolar plates of fuel cells and electrode plates of electrolytic cells include graphite, polymer-graphite composites, carbon-carbon composites.

1. Graphite

Graphite is a common material for manufacturing bipolar plates of fuel cells. Because graphitic bipolar plates have been long-used in fuel cells, the data of actual observation records, reliability analyses and life span tests are complete. So conductivity, anticorrosion, gas proofness and mechanical properties of graphite are often used as technical standards for bipolar plates and other components of fuel cells. Because graphitic bipolar plates are manufactured by sintering repeatedly at a temperature between 2000° C. and 2500° C. and then CNC machining to form delicate flow channels, the manufacturing processes of graphitic bipolar plates are complicated and the products are also brittle. Consequently, graphitic bipolar plates are rather expensive and can be 30% of a fuel cell's total cost. Accordingly, identifying cheap alternatives to graphite was necessary as fuel cells have become more popular.

2. Polymer-Graphite Composites

Polymer-graphite composites are cheaper than graphite and flow channels can be formed easily by injection molding so the costs of material and machining are reduced. Anticorrosion of polymer-graphite composites is also similar to graphite so polymer-graphite composites are used more and more on bipolar plates of polymer electrolyte membrane fuel cells (PEMFC). However, because conductivity of polymer-graphite composites is still lower than graphite, electrical efficiency of PEMFCs with polymer-graphite composites is less than that of PEMFCs with graphite. In addition, gas proofness and mechanical properties of polymer-graphite composites are also less than those of graphite. Furthermore, reliability analyses and life span tests of polymer-graphite composites still need to be established.

3. Carbon-Carbon Composites

Because carbon-carbon composites are manufactured by repeated impregnation and high-temperature graphitization, carbon and carbon composites are expensive relative to other materials though cheaper than graphite.

4. Metals

Generally speaking, the prevalent trend for bipolar plates in fuel cells in the future appears to be metal bipolar plates because of low cost of metals. Conductivity, mechanical properties and gas proofness of metals are also higher than those of graphite. Flow channels can also be formed easily in metals by stamping. However, the major disadvantage is their susceptibility to corrosion. The fuel cell environment is hostile and metals like stainless steel, nickel alloy or aluminum alloy corrode in a fuel cell environment and release metal ions that poison proton exchange membranes such as Nafion (DuPont) and nano platinum catalyst. Finally, the electrical efficiency of PEMFCs with metal bipolar plates gradually decreases. Therefore, current metal bipolar plates are often coated with an anticorrosive TiN film.

However, because conductivity of TiN is lower than graphite, a gold (Au) or platinum (Pt) coating is formed on the TiN film to lower contact resistance of metal bipolar plates, which makes the bipolar plates considerably more expensive. In addition, anticorrosion of the metal bipolar plates with TiN film and an Au or Pt coating (life span: about 2000 hours) is still lower than that of graphite bipolar plates (life span: more than 5000 hours). Other anticorrosive coatings such as diamond-like carbon film or polymer film deposited by plasma enhanced chemical vapor deposition (PECVD) also have low conductivity. Hence, a major task of popularizing fuel cells is to improve anticorrosion of metal bipolar plates without decreasing conductivity of the metal bipolar plates.

One method of improving anticorrosion of metal bipolar plates is to form conductive carbon film on metal bipolar plates. Conventional technologies of forming conductive carbon material are used primarily to manufacture carbon nanotube powders, carbon nanotube display boards or carbon nanotube light emitting devices. For example, an arrayed nickel pad is formed by lithography and etching, and an emitting electrode of an arrayed carbon nanotube is formed on the arrayed nickel pad by PECVD at a high temperature of more than 900° C. for applications such as a flat panel display.

Another common method of manufacturing carbon film is a thermally decomposed polymer coating method. The method comprises a step of coating a metal substrate with a specific polymer such as acetylenic polymer. Then the polymer is thermally decomposed to form a coating containing a carbon content greater than 90% to protect the metal substrate. However, the carbon film formed by this method is thicker than the carbon film formed by chemical vapor decomposition. Adhesion and evenness of the carbon film formed by this method are also inferior to those of a carbon film formed by chemical vapor decomposition.

Another method comprises a step of injection molding a layer of conductive polymer composite on an aluminum substrate having flow channels. However, because the layer of conductive polymer composite is not completely gas proof and is not capable of isolating the aluminum substrate from the hostile fuel cell environment, a coating of noble metals, TiN or CrN needs to be formed on the aluminum substrate. Accordingly, the manufacturing processes are also complicated and expensive.

To overcome the shortcomings, the present invention provides a method of forming a carbon film on a metal substrate at a low temperature to mitigate or obviate the aforementioned problems.

### SUMMARY OF THE INVENTION

The primary objective of the present invention is to provide a method of forming a conductive and anticorrosive carbon film on a metal substrate at a low temperature.

A method of forming a carbon film on a metal substrate at a low temperature in accordance with the present invention comprises steps of preparing a metal substrate, forming a catalytic layer on the metal substrate and forming a carbon film on the catalytic layer by chemical vapor deposition (CVD).

In the step of preparing a metal substrate, the metal substrate has a softening temperature.

In the step of forming a catalytic layer on the metal substrate, the catalytic layer has a thickness greater than 0.01 μm.

In the step of forming a carbon film on the catalytic layer by chemical vapor deposition (CVD), a carbonaceous material is carried into a CVD reaction area by a carrier gas and is thermally decomposed and dehydrogenated at a reaction temperature lower than the softening temperature of the metal substrate and between 300° C. and 1000° C. to form the carbon film having a thickness between 0.1 μm and 10 μm on the catalytic layer.

Other objectives, advantages and novel features of the invention will become more apparent from the following detailed description when taken in conjunction with the accompanying drawings.

### BRIEF DESCRIPTION OF THE DRAWINGS

FIG. 1 is a block diagram of a method of forming a carbon film on a metal substrate at a low temperature in accordance with the present invention;

FIG. 2 is a plot of the change in temperature over time during the method of forming a carbon film in Example 1; and

FIG. 3 is plots of polarization curves of test pieces and graphite in Example 2.

### DETAILED DESCRIPTION OF THE INVENTION

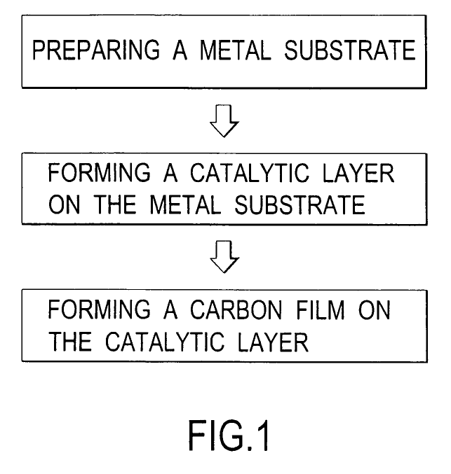

With reference to FIG. 1, a method of forming a carbon film on a metal substrate at a low temperature in accordance with the present invention comprises steps of preparing a metal substrate, forming a catalytic layer on the metal substrate and forming a carbon film on the catalytic layer.

The step of preparing a metal substrate comprises preparing a metal substrate having a softening temperature. The metal substrate can be stainless steel, nickel alloy, plain carbon steel, aluminum alloy, copper alloy or titanium alloy substrates.

The step of forming a catalytic layer on the metal substrate comprises forming a catalytic layer having a thickness of greater than 0.01 μm on the metal substrate surface. To form a carbon film of high graphitization degree at a reaction temperature lower than the softening temperature of the metal substrate, the catalytic layer is formed to catalyze graphitization of the carbon film and lower the reaction temperature. Research suggested that Ni, Co, Fe, Pt, Pd, Ag, Au and alloys of at least two of those have a capacity of catalyzing graphitization of a carbon film and can be used for the catalytic layer. Consequently, the catalytic layer can be formed at a temperature substantially lower than the reaction temperature of forming a carbon film of high graphitization degree. In addition, thickness of the catalytic layer considerably affects forming pattern of the carbon film. When the thickness of the catalytic layer is less than 0.01 μm, islands of catalytic particles may be produced. Consequently, tubular, fibrous or spherical carbon objects may be formed on the catalytic layer instead of a fine carbon film. The thickness of the catalytic layer can be greater than 1 μm as long as the catalytic layer does not peel away from the metal substrate. The catalytic layer can be formed by evaporation, sputtering, electroplating or electroless plating.

The step of forming a carbon film on the catalytic layer comprises forming a carbon film by chemical vapor deposition (CVD) and is performed by carrying a carbonaceous material into a CVD reaction area by a carrier gas and thermally decomposing and dehydrogenating the carbonaceous material at a reaction temperature between 300° C. and 1000° C. to form a carbon film having a thickness between 0.1 μm and 10 μm on the catalytic layer. If the thickness of the carbon film is less than 0.1 μm, the carbon film is not capable of isolating the metal substrate from the hostile fuel cell environment. If the thickness of the carbon film is greater than 10 μm, the carbon film may crack easily.

The carbon film is formed by CVD rather than PVD because the carbon film formed with PVD may have a diamond-like structure having lower conductivity. CVD used in this step can be thermally decomposed chemical vapor deposition, plasma enhanced chemical vapor deposition (PECVD) or microwave chemical vapor deposition.

The carbonaceous material can be decomposed and dehydrogenated at a low temperature and may be a gas such as methane, acetylene or ethylene, a liquid such as methanol or ethanol or a solid such as olefin or camphor. A transition metal compound can be added to the carbonaceous material to modify the transition metal content in the carbon film and adjust conductivity and mechanical properties of the carbon film. The transition metal compound can be titanamide (Ti(NH₂)₄), titanium tetrachloride (TiCl₄), molybdenum hexacarbonyl (Mo(CO)₆), tungsten hexacarbonyl (W(CO)₆), chromium carbonyl (Cr(CO)₆). The carrier gas can be an inert gas such as argon or helium or a reductive gas such as nitrogen, hydrogen or ammonia.

The volumetric ratio of the carbonaceous material to the carrier gas affects the graphitization degree of the carbon film, which can be indicated by a graphitization index (R) measured by a Raman spectrometer. The graphitization index (R) can be expressed by the following equation: R=R_{D}/R_{G}, where R_{D} is a D-band integral value of a Raman spectrum and R_{G} is a G-band integral value of a Raman spectrum. The graphitization degree increases as the graphitization index (R) decreases. When the graphitization index (R) is zero, the graphitization degree is 100%. Taking a mixed gas of acetylene and hydrogen as an example, a carbon film of high graphitization degree (0.015<R<3) can be formed when the volumetric ratio of acetylene and hydrogen is greater than 0.015. Preferably, the volumetric ratio of acetylene and hydrogen is between 0.015 and 15. The operating gas pressure in the CVD reaction area is between 0.001 torr and 760 torr.

### EXAMPLE 1

Three test pieces were prepared, and each test piece was comprised of a metal substrate and a catalytic layer. The metal substrate was AISI 304 stainless steel. The catalytic layer was Ni, was formed on the metal substrate and was from 0.4 μm to 0.8 μm thick.

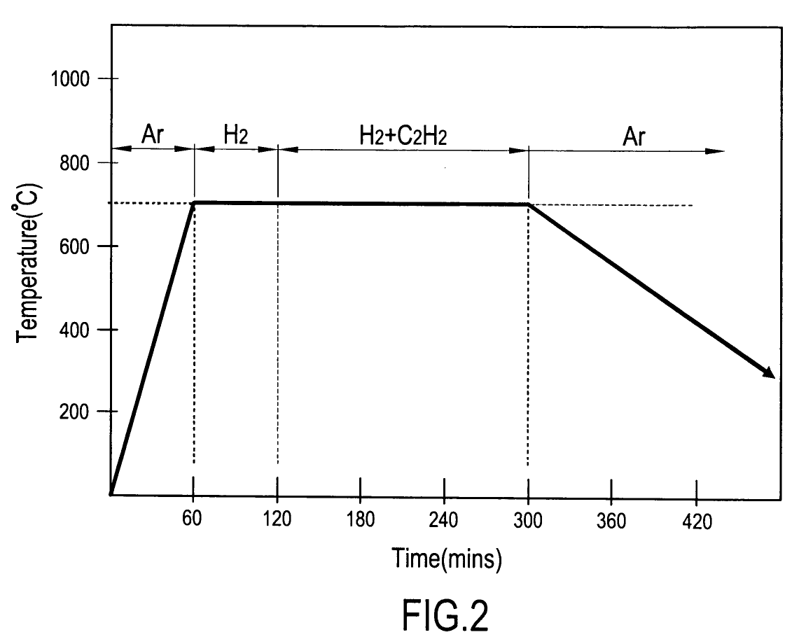

With reference to FIG. 2, the test pieces are placed in a tubular CVD furnace and were subjected to a thermally decomposed CVD reaction at various reaction temperatures. First, the tubular CVD furnace was subjected to a vacuum pressure of 0.001 torr. Then the furnace was flushed with Ar gas at 1 atm and was heated to a temperature of 700° C. in 1 hour. After the furnace was flushed, the catalytic layer was reduced with hydrogen at 1 atm for 1 hour at 700° C. Finally, a mixed gas of 33 vol % acetylene and 67 vol % hydrogen flows through the furnace at 1 atm for 3 hours to perform the thermally decomposed CVD reaction to form a carbon film on the catalytic layer of Ni.

After the thermally decomposed CVD reaction is complete, the mixed gas is cut off, and Ar gas is introduced to dilute the mixed gas, terminate the thermally decomposed CVD reaction and prevent high-temperature oxidation. After the furnace cooled down to the room temperature, the test pieces were removed from the furnace, and sheet resistances of the test pieces were measured by a four-probe method. Sheet resistances of graphite and stainless steel were also measured for comparison.

TABLE 1
Sheet resistances of the test pieces with different thicknesses
of the catalytic layer of Ni, stainless steel and graphite.

| Material | Sheet resistance (10⁻⁴Ω/cm²) |
|---|---|
| Stainless steel/catalytic layer of | 4.805 |
| Ni (0.4 μm)/carbon film (1.5 μm) | |
| Stainless steel/catalytic layer of | 4.901 |
| Ni (0.6 μm)/carbon film (1.5 μm) | |
| Stainless steel/catalytic layer of | 5.304 |
| Ni (0.8 μm)/carbon film (1.5 μm) | |
| Stainless steel | 4.746 |
| Graphite | 6.220 |

From the results of the measurements of sheet resistances, sheet resistances of the test pieces were close to that of the stainless steel and were lower than graphite. Sheet resistance rose slightly when the thickness of the catalytic layer of Ni increased. The results demonstrated that the test pieces having a carbon film formed by the method in accordance with the present invention were more conductive than graphite.

### EXAMPLE 2

Six test pieces were prepared, and each test piece was comprised of a metal substrate and a catalytic layer. The metal substrate was AISI 304 stainless steel. The catalytic layer was Ni, was formed on the metal substrate and had a thickness of 0.4 μm. The test pieces were placed in a tubular CVD furnace and were subjected to a thermally decomposed CVD reaction similar to example 1 at different reaction temperatures (500, 600, 650, 700, 750 and 800° C.). A mixed gas of 60 vol % acetylene and 40 vol % hydrogen was flowed through the furnace for 3 hours to carry out the thermally decomposed CVD reaction to form a carbon film on the catalytic layer of Ni.

After the thermally decomposed CVD reaction was complete, the microstructure of the carbon film on each test piece was observed with an optical microscope. From the results of observation, the microstructure of the carbon film was affected considerably by the reaction temperature. When the reaction temperature was 500° C., the carbon material was deposited loosely and unevenly on the catalytic layer without forming a carbon film. When the reaction temperature was 600° C., the carbon material was deposited evenly but discontinuously on the catalytic layer. When the reaction temperature was 650 and 700° C., a continuous carbon film was formed evenly on the catalytic layer. When the reaction temperature was 750° C., the carbon film was cracked. When the reaction temperature was 800° C., the carbon film peeled off the catalytic layer.

### EXAMPLE 3

Two test pieces were prepared, and each test piece was comprised of a metal substrate and a catalytic layer. The metal substrate was stainless steel. The catalytic layer was Ni, was formed on one of the test pieces and was 0.6 μm thick. The test pieces are placed in a tubular CVD furnace and were subjected to a thermally decomposed CVD reaction similar to example 1 at a reaction temperature of 700° C. A mixed gas of 50 vol % acetylene and 50 vol % hydrogen was flowed through the furnace for 3 hours to carry out the thermally decomposed CVD reaction to form a carbon film on the test piece.

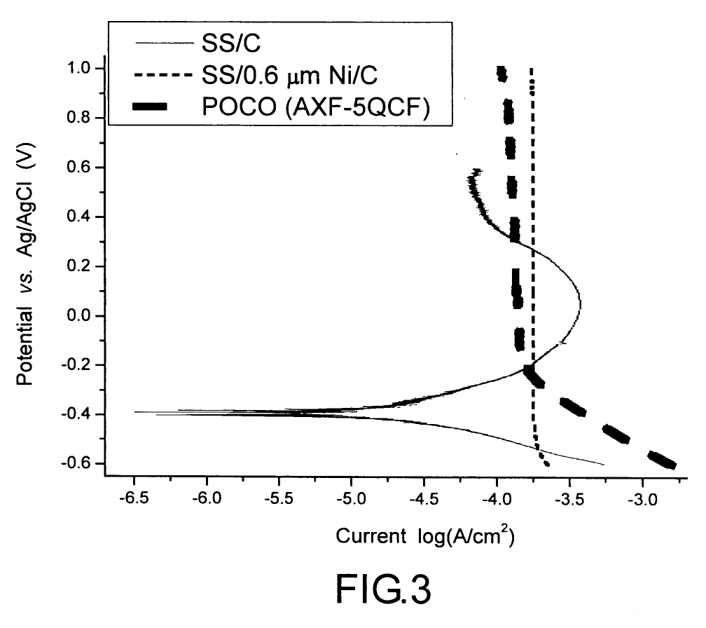

After the thermally decomposed CVD reaction was complete, polarization of the test pieces and graphite (POCO, AXF-5QCF) were measured in a sulfuric acid solution with a potentiostat by using Ag/AgCl as a reference electrode and Pt as an auxiliary electrode and polarization curves were obtained. With reference to FIG. 3, the scanning range of potential was between −0.6 V and +1.0 V. The scanning rate was 10 mV/s. The polarization curves of the test piece without catalytic layer (SS/C) exhibited typical metallic corrosion behavior (Tafel behavior) having a corrosion potential of −0.4 V. Because the carbon film formed on the test piece (SS/C) was discontinuous, sulfuric acid passed through the carbon film and corroded the stainless steel metal substrate. The polarization curve of the test piece having a catalytic layer (SS/0.6 μm Ni/C) exhibited no metallic corrosion behavior. The reaction current was rather weak (about 10⁻⁴ A/cm²) and was almost constant at high or low potentials. The signal of the reaction current results from the current produced by absorption and desorption of hydrogen ions by the carbon film, not corrosion of the metal substrate. Because a fine and continuous carbon film was formed on the test piece (SS/0.6 μm Ni/C), the metal substrate was not corroded by the sulfuric acid. The polarization curve of the test piece (SS/0.6 μm Ni/C) is similar to that of graphite (POCO, AXF-5QCF), which demonstrates that anticorrosiveness of the test piece (SS/0.6 μm Ni/C) was close to graphite (POCO, AXF-5QCF).

After the polarization curves are recorded, metal content in the sulfuric acid solutions of the test pieces and graphite were also measured with an inductively coupled plasma-mass spectrometer (ICP-MS).

TABLE 2
Metal contents in the sulfuric acid solutions

| | | | (unit: ppm) |
|---|---|---|---|
| Material | Ni | Fe | Cr |
| Test piece (SS/C) | 1.584 | 8.175 | 1.725 |
| Test piece (SS/0.6 μm Ni/C) | *nil | nil | nil |
| Graphite (POCO, AXF-5QCF) | nil | nil | nil |

*nil: signal of the element cannot be detected by the ICP-MS.

The metal content results show that the elements (Ni, Fe, Cr) contained in the metal substrate of stainless steel of the test piece (SS/C) dissolved into the sulfuric acid solution, while no metal element was dissolved into the sulfuric acid solutions of the test piece (SS/0.6 μm Ni/C) and graphite (POCO, AXF-5QCF).

### EXAMPLE 4

Six test pieces were prepared, and each test piece was comprised of a metal substrate and a catalytic layer. The metal substrate was AISI 1040 carbon steel (0.4 wt % C). The catalytic layer was Ni, was formed on the test piece and was from 0.4 μm to 1.0 μm thick. The test pieces were placed in a tubular CVD furnace and subjected to a thermally decomposed CVD reaction similar to example 1 at a reaction temperature of 850° C. Different mixed gases (methane-hydrogen and methane-Ar) were flowed through the furnace for 3 hours to carry out the thermally decomposed CVD reaction to form a carbon film on each test piece.

After the thermally decomposed CVD reaction was complete, graphitization degrees of the carbon films of the test pieces were measured with a Raman spectrometer.

TABLE 3
Graphitization degrees of the carbon films of the test pieces.

| Test piece | Mixed gas (vol %) | *R |
|---|---|---|
| Carbon steel/0.4 μm Ni/1.5 μm carbon | 50 methane-50 Ar | 1.11 |
| Carbon steel/0.4 μm Ni/1.5 μm carbon | 33 methane-67 Ar | 1.01 |
| Carbon steel/0.4 μm Ni/1.5 μm carbon | 33 methane-67 hydrogen | 0.06 |
| Carbon steel/1.0 μm Ni/1.5 μm carbon | 50 methane-50 Ar | 1.06 |
| Carbon steel/1.0 μm Ni/1.5 μm carbon | 33 methane-67 Ar | 0.80 |
| Carbon steel/1.0 μm Ni/1.5 μm carbon | 33 methane-67 hydrogen | 0.10 |

*R = R_{D}/R_{G}, where R_{D} is a D-band integral value of a Raman spectrum and R_{G} is a G-band integral value of a Raman spectrum. The graphitization degree is higher when the graphitization index (R) is lower. When the graphitization index (R) is zero, the graphitization degree is 100%.

The results of graphitization degree tests demonstrate that composition of the mixed gas had a remarkable effect on the graphitization degree. The graphitization degree of the carbon film formed with the mixed gas of methane-hydrogen was higher than that of the carbon film formed with the mixed gas of methane-Ar. When the mixed gas was 33 vol % methane-67 vol % hydrogen, the graphitization degrees of the carbon films are near 100% (R=0.06 and 0.10). The graphitization degree of the carbon film with a thicker catalytic layer (1.0 μm) was higher than that of the carbon film with a thinner catalytic layer (0.4 μm). Example 4 demonstrates that optimizing operation parameters of the CVD reaction can produce a carbon film of high graphitization degree and improve electrical characteristics such as conductivity and contact resistance of the carbon film. When composition of the reaction gas was optimized, a carbon film of nearly 100% graphitization or with an R value near zero was produced.

The method in accordance with the present invention has the following advantages.

1. Improving Anticorrosiveness of the Metal Substrate

A carbon film has better anticorrosiveness than protective films such as TiN, metal carbides and metal oxides. So forming a carbon film on the metal substrate keeps the metal substrate from being corroded by the hostile fuel cell environment.

2. Increasing Conductivity of the Carbon Film

Because the carbon film formed by PVD has a diamond-like structure that is nonconducting, the method in accordance with the present invention uses CVD to form a carbon film of high graphite degree. Because the carbon film formed by the method in accordance with the present invention comprises a conductive graphite and amorphous carbon structure, the carbon film is conductive.

3. Reducing the Reaction Temperature of CVD

Generally, the heat treatment temperature of graphitization and carbon fiber is over 1000° C. Some high-density graphite materials must be heated to more than 2000° C. and be impregnated repeatedly. The method in accordance with the present invention forms a catalytic layer on the metal substrate to reduce the reaction temperature to less than 1000° C. and facilitate carrying out CVD on a metal substrate having a low softening temperature.

4. Forming a Continuous and Fine Carbon Film

Manufacturing carbon materials with a high graphitization degree usually requires heating the carbon materials to temperatures greater than 1000° C. Carbon material of nearly 100% graphitization degree must be heated to a temperature greater than 1800° C. However, these carbon materials are loose and are not capable of forming a fine carbon film. The carbon film formed by the method in accordance with the present invention is produced at a temperature less than 1000° C. so the carbon film is continuous and fine and isolates the metal substrate from the hostile fuel cell environment.

Even though numerous characteristics and advantages of the present invention have been set forth in the foregoing description, together with details of the structure and function of the invention, the disclosure is illustrative only. Changes may be made in detail, especially in matters of shape, size and arrangement of parts within the principles of the invention to the full extent indicated by the broad general meaning of the terms in which the appended claims are expressed.

What is claimed is:

1. A method of forming a carbon film on a metal substrate at a low temperature comprising steps of
preparing a metal substrate having a softening temperature;
forming a catalytic layer having a thickness greater than 0.01 μm on the metal substrate; and
forming a carbon film on the catalytic layer by chemical vapor deposition (CVD) at a reaction temperature lower than the softening temperature of the metal substrate, wherein a carbonaceous material is carried into a CVD reaction area by a carrier gas and is thermally decomposed at a reaction temperature between 300° C. and 1000° C. to form the carbon film having a thickness between 0.1 μm and 10 μm on the catalytic layer.

2. The method as claimed in claim 1, wherein the CVD is thermally decomposed chemical vapor deposition, plasma enhanced chemical vapor deposition (PECVD) or microwave chemical vapor deposition.

3. The method as claimed in claim 1, wherein the metal substrate is stainless steel, nickel alloy, plain carbon steel, aluminum alloy, copper alloy or titanium alloy substrates.

4. The method as claimed in claim 1, wherein the material of the catalytic layer is Ni, Co, Fe, Pt, Pd, Ag, Au or alloys of at least two of those.

5. The method as claimed in claim 1, wherein the catalytic layer is formed by evaporation, sputtering, electroplating or electroless plating.

6. The method as claimed in claim 1, wherein the method further comprises a step of reducing the catalytic layer with hydrogen before the step of forming a carbon film on the catalytic layer.

7. The method as claimed in claim 1, wherein the carbonaceous material is methane, acetylene, ethylene, methanol, ethanol, olefin or camphor.

8. The method as claimed in claim 1, wherein the carrier gas is argon, helium, nitrogen, hydrogen or ammonia.

9. The method as claimed in claim 1, wherein a transition metal compound is added to the carbonaceous material and is titanamide (Ti(NH₂)₄), titanium tetrachloride (TiCl₄), molybdenum hexacarbonyl (Mo(CO)₆), tungsten hexacarbonyl (W(CO)₆) or chromium carbonyl (Cr(CO)₆).

10. The method as claimed in claim 1, wherein the operating gas pressure in the CVD reaction area is between 0.001 torr and 760 torr.

11. The method as claimed in claim 2, wherein the carrier gas is hydrogen.

12. The method as claimed in claim 11, wherein the carbonaceous material is methane.

13. The method as claimed in claim 12, wherein methane is 33 vol % and hydrogen is 67 vol %.

14. The method as claimed in claim 13, wherein the reaction temperature is between 800° C. and 1000° C.

15. The method as claimed in claim 14, wherein the metal substrate is stainless steel substrate.

16. The method as claimed in claim 15, wherein the material of the catalytic layer is Ni.

17. The method as claimed in claim 11, wherein the carbonaceous material is acetylene.

18. The method as claimed in claim 17, wherein volumetric ratio of acetylene to hydrogen is between 0.015 and 15.

19. The method as claimed in claim 18, wherein the reaction temperature is between 600° C. and 850° C.

20. The method as claimed in claim 14, wherein the metal substrate is stainless steel substrate.
